(19) United States
(12) Patent Application Publication
(10) Pub. No.: US 2009/0166893 A1
(43) Pub. Date: Jul. 2, 2009

(54) SEMICONDUCTOR DEVICE

(75) Inventors: Keiji Okumura, Kyoto-fu (JP); Takukazu Otsuka, Kyoto-fu (JP); Masao Saito, Kyoto-fu (JP)

Correspondence Address: FISH & RICHARDSON P.C., P.O. BOX 1022, MINNEAPOLIS, MN, 55440-1022, US

(73) Assignee: ROHM CO., LTD., Kyoto-fu (JP)

(21) Appl. No.: 12/342,161

(22) Filed: Dec. 23, 2008

(30) Foreign Application Priority Data
Dec. 27, 2007 (JP) 2007-337445

(51) Int. Cl. H01L 23/49

(52) U.S. Cl. 257/784; 257/E23.024

(57) ABSTRACT

A semiconductor device according to the present invention includes: an insulating substrate; a metal bonding member being disposed on the insulating substrate and having a porous region and a metal region, the porous region being provided with multiple pores therein and being adjacent to the metal region in a plane direction of the insulating substrate; a solder material impregnated into the pores; a semiconductor element disposed on the surface of the porous region in the metal bonding member; a bonding wire connected to the surface of the metal region in the metal bonding member. This makes it possible to provide a semiconductor device having improved electrical conductivity and thermal conductivity, and enabling the weight reduction.

### BACKGROUND OF THE INVENTION

1. Field of the Invention

The present invention relates to a semiconductor device, and particularly to a semiconductor device having improved electrical conductivity and thermal conductivity.

2. Description of Related Art

In a manufacturing process of a semiconductor power module, it is conventionally well known that a solder is used for bonding a semiconductor chip to a substrate.

FIG. 4 shows one structural example of a conventional semiconductor power module. Specifically, in the conventional semiconductor power module, conductors 4, 5 such as metals are disposed on the bottom surface and the top surface of an insulating substrate 3, respectively. A semiconductor element 1 is bonded to a region of the conductor 5 with a solder 20. A bonding wire 6 is bonded to another region of the conductor 5. A current is conducted to the semiconductor element 1 through the bonding wire 6 and the conductors 4, 5.

However, in a normal solder bonding, the semiconductor power module is subjected to thermal cycles during the repetitions of conducting and non-conducting electricity to the semiconductor element 1. Accordingly, a strain is put on the solder 20 due to the difference in thermal expansion coefficient between the solder 20 and the insulating substrate 3 or the semiconductor element 1. This may result in a problem of crack generation in some cases.

In order to solve this problem, Japanese Patent Application Publication No. 2004-298962, for example, discloses that bonding is performed with a solder bonding material that is a three-dimensional mesh structured and porous metal containing a solder, instead of bonding with a solder, to reduce strain generation.

Nevertheless, in the above conventional technique, when the use of wire bonding is taken into consideration for the power module and the wire is connected to the conductor in that structure, electricity is conducted through the conductor and heat is dissipated therethrough also. For this reason, it has been difficult to improve the electrical conductivity and thermal conductivity.

### SUMMARY OF THE INVENTION

An object of the present invention is to provide a semiconductor device having improved electrical conductivity and thermal conductivity and enabling weight reduction.

To accomplish the above object, an aspect of the present invention provides a semiconductor device including: an insulating substrate; a metal bonding member being disposed on the insulating substrate and having a metal region and a porous region being provided with multiple pores therein and being adjacent to the metal region in a plane direction of the insulating substrate; a solder material impregnated into the pores; a semiconductor element disposed on a surface of the porous region; and a bonding wire connected to a surface of the metal region in the metal bonding member.

According to the semiconductor device of the present invention, it becomes possible to provide a semiconductor device having improved electrical conductivity and thermal conductivity and enabling weight reduction.

### BRIEF DESCRIPTION OF THE DRAWINGS

FIG. 1 is a schematic cross-sectional view of a structure of a semiconductor device according to a first embodiment of the present invention.

FIGS. 2A to 2E are explanatory drawings of a method for manufacturing the semiconductor device according to the first embodiment of the present invention; FIG. 2A is a process drawing in which a porous metal sheet 2c having multiple pores 7 is formed; FIG. 2B is a process drawing in which the porous metal sheet 2c is bonded to a metal sheet 2d; FIG. 2C is a process drawing in which a metal bonding member 2 is formed; FIG. 2D is a process drawing in which the metal bonding member 2 is formed on an insulating substrate 3; and FIG. 2E is a process drawing in which a semiconductor element 1 is formed on the metal bonding member 2.

FIG. 3 is a schematic cross-sectional view of a structure of a semiconductor device according to a second embodiment of the present invention.

FIG. 4 is a schematic cross-sectional view of a structure of a conventional semiconductor device.

### DETAILED DESCRIPTION OF THE PREFERRED EMBODIMENTS

Hereinafter, semiconductor devices according to embodiments of the present invention will be described with reference to the drawings. In the description on the drawings below, the same or similar components are denoted by the same or similar symbols, respectively. However, the drawings are schematic and thus differ from the actual. Additionally, it should be noted that, even though denoted by the same symbols, some components may differ in dimensional relation and ratio in one drawing from the others.

### First Embodiment

### (Structure of Semiconductor Device)

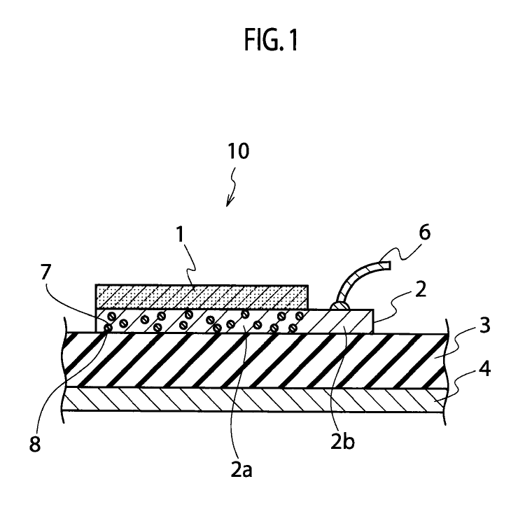

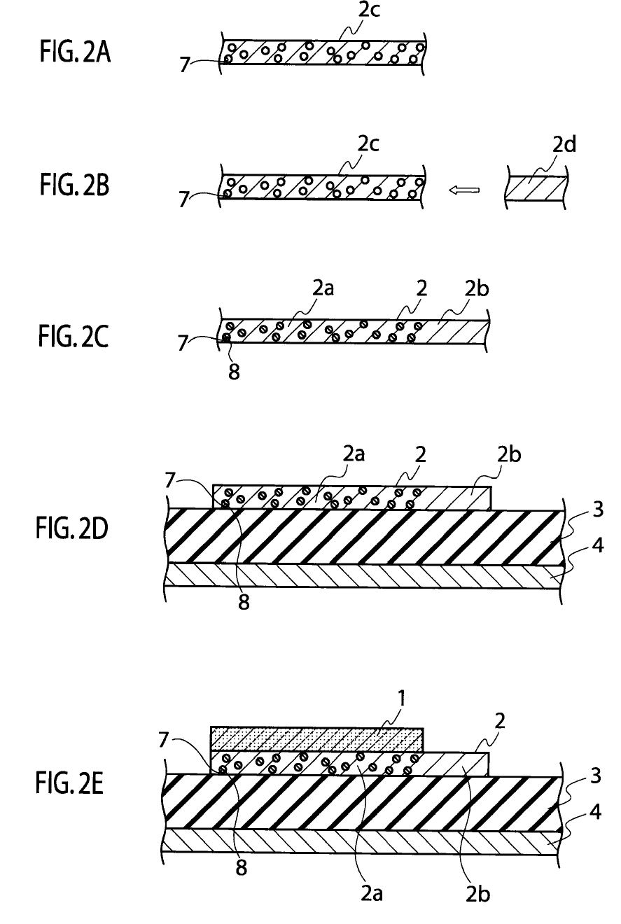

A semiconductor power module as a semiconductor device according to a first embodiment of the present invention will be described with reference to FIGS. 1 and 2A to 2E.

As shown in FIG. 1, the semiconductor power module of the first embodiment includes: an insulating substrate 3; a metal bonding member 2 being disposed on the insulating substrate 3 and having a porous region 2a and a metal region 2b, the porous region 2a being provided with multiple pores 7 therein and being adjacent to the metal region 2b in a plane direction of the insulating substrate 3; a solder material 8 impregnated into the pores 7; a semiconductor element 1 disposed on the surface of the porous region 2a in the metal bonding member 2; and a bonding wire 6 connected to the surface of the metal region 2b in the metal bonding member 2.

The semiconductor element 1 is, for example, an insulated gate bipolar transistor (IGBT). An emitter electrode and a gate electrode are formed on one surface side of the semiconductor element 1. A collector electrode is formed on the other surface side thereof. The collector electrode is bonded to the porous region 2a in the metal bonding member 2 on the side of the insulating substrate 3. The emitter electrode and the gate electrode are each connected to an external connection terminal or the like.

The insulating substrate 3 is formed of ceramics such as alumina having an excellent thermal conductivity. As described above, the collector electrode of the semiconductor element 1 is bonded to the top surface of the insulating substrate 3 with the metal bonding member 2 interposed therebetween. On the bottom surface of the insulating substrate 3, a conductor 4 that constitutes a conduction pattern for wiring or the like may be disposed. Furthermore, a heat dissipator made of, for example, copper may be disposed under the conductor 4.

The metal bonding member 2 is made of a metal. In the metal bonding member 2, the porous region 2a having the multiple pores 7 therein and the metal region 2b made only of the metal portion are disposed adjacent to each other in the plane direction of the insulating substrate 3. The thickness of the metal bonding member 2 is approximately 0.1 mm to 2.0 mm, and preferably approximately 0.2 mm to 1.0 mm.

The porous region 2a is disposed in a region of the metal bonding member 2, the region including a surface which is bonded to the semiconductor element 1. The metal region 2b is disposed in a region of the metal bonding member 2, the region including a surface which is not bonded to the semiconductor element 1.

The pores 7 in the porous region 2a are continuous with each other, and have an open pore structure. The average diameter of the pores 7 is approximately 1 μm to 1000 μm, and preferably approximately 100 μm to 500 μm. The porosity of the pores 7 is approximately 70% to 95%, and preferably approximately 80% to 90%.

Note that the porosity refers to a value calculated by the following equation:

porosity (%)={1−(ρ₁/ρ₀)}×100,

where ρ₁ represents a bulk density obtained from the measurements of volume and weight, and ρ₀ represents a true density of the metal.

The material of the metal bonding member 2 is not particularly limited as long as the material is an electroconductive metal having a sufficient strength. The metal bonding member 2 is preferably made of, for example, copper, aluminum, nickel, or the like.

The pores 7 are impregnated with the solder material 8. As the material of the solder material 8, lead-tin based solders, tin-zinc based solders, tin-indium based solders, tin-silver-copper based solders, or the like can be used.

The bonding wire 6 is a conductor for conducting electricity to the collector electrode of the semiconductor element 1. The bonding wire 6 is connected to the surface of the low-porosity region 2b of the metal bonding member 2. As the material of the bonding wire 6, a metal such as copper, aluminum, and gold can be used.

### (Operation Principle)

The semiconductor device according to the first embodiment of the present invention operates on the basis of the following principles.

In a semiconductor device 10, voltages are applied to the external connection terminals connected respectively to the emitter electrode and the gate electrode of the semiconductor element 1 as well as the bonding wire 6 connected to the collector electrode via the metal bonding member 2. The voltages applied to the emitter electrode, the gate electrode and the collector electrode are controlled, so that the semiconductor element 1 is operated.

### (Manufacturing Method)

FIGS. 2A to 2E are explanatory drawings of a method for manufacturing the semiconductor device according to the first embodiment of the present invention.

The method for manufacturing the semiconductor device according to the first embodiment of the present invention includes the steps of: forming a porous metal sheet 2c having multiple pores 7; weld-bonding one edge surface of the porous metal sheet 2c to one edge surface of a metal sheet 2d to form a metal bonding member 2 including a porous region 2a and a metal region 2b; impregnating the pores 7 in the metal bonding member 2 with a solder material 8; bonding the solder material 8 to the top surface of an insulating substrate 3 to form the metal bonding member 2 on an insulating substrate 3; forming a semiconductor element 1 on the surface of the porous region 2a in the metal bonding member 2; and bonding a wire on the surface of the metal region 2b in the metal bonding member 2.

Hereinafter, the manufacturing steps will be described in detail.
(a) First of all, as shown in FIG. 2A, the porous metal sheet 2c having the multiple pores 7 used in the first embodiment of the present invention can be prepared as follows.

Firstly, a slurry is prepared in which metal powders such as copper powers are dispersed in a resin binder containing a foaming agent made of a water-insoluble organic solvent.

After this slurry is formed into a sheet, the dispersedly trapped water-insoluble organic solvent is made to evaporate. During the evaporation, the multiple pores 7 are formed due to the volume expansion, and a porous body is thus formed.

The porous metal sheet 2c can be obtained, after the porous body is dried and sintered in a reducing atmosphere. The resin of the resin binder or the like is removed through a degreasing process.

Incidentally, the porosity can be controlled, before the porous metal sheet 2c is sintered, by pressuring and heating the porous body.
(b) Then, as shown in FIG. 2B, one edge surface of the porous metal sheet 2c is bonded, by welding or the like, to an edge surface of the metal sheet 2d made of a metal such as copper. Thus, the metal bonding member 2 including the porous region 2a and the metal region 2b is formed.
(c) Subsequently, as shown in FIG. 2C, the pores 7 formed in the porous region 2a of the metal bonding member 2 are impregnated with the solder material 8 made of, for example, tin and indium.
(d) Thereafter, as shown in FIG. 2D, a conductor 4 made of copper or the like is formed by means of, for example, sputtering on the bottom surface of the insulating substrate 3 formed of alumina or the like.

The metal bonding member 2 is formed on the top surface of the insulating substrate 3. In order to prevent oxide film formation on the solder material 8, the solder material 8 is bonded to the top surface of the insulating substrate 3 in a reducing atmosphere such as formic acid. Thereby, the metal bonding member 2 is bonded to the insulating substrate 3.
(e) After that, as shown in FIG. 2E, the semiconductor element 1 is formed on the surface of the porous region 2a in the metal bonding member 2.
(f) Finally, the wire is bonded to the surface of the metal region 2b in the metal bonding member 2, and thus the formation of a semiconductor device 10 shown in FIG. 1 is completed.

In the semiconductor device 10, the porous region 2a and the metal region 2b are electrically connected to each other through the metal material of the metal bonding member 2. For this reason, the bonding of the wire to the metal region 2b, i.e., a metal region not containing the solder material 8, in the metal bonding member 2 eliminates the need for the wire bonding through the conductor and the solder as in the case of the conventional technique. Thus, the electrical conductivity is improved.

Moreover, since the metal bonding member 2 is directly bonded to the insulating substrate 3, heat not only from the solder material 8 but also from the metal material of the metal bonding member 2 is conducted to the insulating substrate 3. Thereby, heat generated during electricity conduction to the semiconductor element 1, for example, can be dissipated efficiently toward the insulating substrate 3.

Furthermore, unlike the conventional technique, the conductor is not disposed between the solder bonding material and the insulating substrate. Thereby, the weight of the semiconductor device is reduced.

According to the semiconductor device in the first embodiment of the present invention, the electrical conductivity and the thermal conductivity are improved, and the weight reduction is achieved.

### Second Embodiment

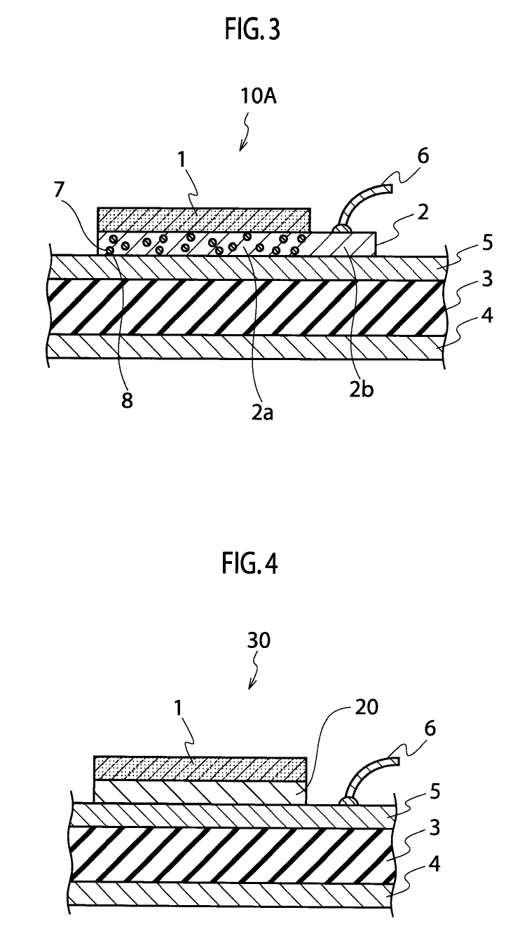

A semiconductor device according to a second embodiment of the present invention will be described with reference to FIG. 3. Note that, in the second embodiment, the same components as those in the first embodiment are denoted by the same reference symbols, and the overlapped description will be omitted.

As shown in FIG. 3, the semiconductor device according to the second embodiment of the present invention further includes a conductor 5 between the insulating substrate 3 and the metal bonding member 2. The other configurations of this semiconductor device are the same as those in the first embodiment, and the description thereof will be omitted.

The conductor 5 is disposed between the insulating substrate 3 and the metal bonding member 2. The conductor 5 is bonded to the metal bonding member 2 by the bonding to the solder material 8 of the metal bonding member 2.

The material of the conductor 5 is not particularly limited as long as the material has an electrical conductivity. Copper, aluminum, nickel, or the like can be used as the material of the conductor 5.

A method for manufacturing the semiconductor device according to the second embodiment differs from the manufacturing method according to the first embodiment in forming a conductor 5. The other steps are the same as those in the first embodiment, and the overlapped description will be omitted.

In the method for manufacturing the semiconductor device according to the second embodiment, the conductor 5 is formed by mean of, for example, sputtering on the top surface of the insulating substrate 3. Consequently, a semiconductor device 10A is manufactured.

Since the conductor 5 is bonded to the solder material 8 of the metal bonding member 2, the solder is easily bonded to the metallic conductor 5. Thus, the conductor 5 is desirably bonded to the metal bonding member 2.

According to the semiconductor device in the second embodiment of the present invention, the electrical conductivity and the thermal conductivity are improved, and the weight reduction is achieved.

### Third Embodiment

A semiconductor device according to a third embodiment of the present invention will be described with reference to FIG. 1. Note that, in the third embodiment, the same components as those in the first embodiment are denoted by the same reference symbols, and the overlapped description will be omitted.

In the semiconductor device according to the third embodiment of the present invention, the metal region 2b in the metal bonding member 2 shown in FIG. 1 has a porosity lower than a porosity of the porous region 2a. The other configurations of this semiconductor device are the same as those in the first embodiment, and the description thereof will be omitted.

In the semiconductor device according to the third embodiment, the metal region 2b in the metal bonding member 2 has a porosity of approximately 1% to 10%, and preferably approximately 1% to 5%.

A method for manufacturing the semiconductor device according to the third embodiment differs from the manufacturing method according to the first embodiment in forming a metal bonding member 2. The other steps are the same as those in the first embodiment, and the overlapped description will be omitted.

In the method for manufacturing the semiconductor device according to the third embodiment, before being sintered, a porous metal sheet 2c obtained as in the case of the method for manufacturing the semiconductor device according to the first embodiment is pressured and heated by, for example, hot pressing a region where a bonding wire 6 is connected. Thereby, in a metal bonding member 2 thus formed, a porous region 2a is formed in a non-pressured portion, and a metal region 2b having a porosity lower than a porosity of the porous region 2a is formed in the pressured portion.

According to the semiconductor device in the third embodiment of the present invention, the electrical conductivity and the thermal conductivity are improved, and the reduction weight is achieved.

### Other Embodiments

Hereinabove, the present invention has been described in detail with regard to the first to third embodiments thereof. It is apparent to those skilled in the art that the present invention is not limited to the first to third embodiments described in the present specification. Modification and alternation can be made on the present invention without departing from the spirit and scope of the present invention defined in the description of the claims. Therefore, the description of the present specification merely aims at exemplary explanation, and is not intended to limit the present invention in any way. Hereinbelow, a partially altered form of the above-described first to third embodiments will be described.

For example, it is possible to alter each material constituting the semiconductor device.

In the above-described semiconductor device according to the first embodiment, the case where the IGBT is used as the semiconductor element 1 has been described. Alternatively, a power metal oxide semiconductor field effect transistor (power MOSFET), a diode or a thyristor may be used as the semiconductor element 1.

What is claimed is:

1. A semiconductor device comprising:
an insulating substrate;
a metal bonding member being disposed on the insulating substrate and including:
a metal region; and
a porous region having a plurality of pores therein and being adjacent to the metal region in a plane direction of the insulating substrate;
a solder material impregnated into the pores;
a semiconductor element disposed on a surface of the porous region in the metal bonding member; and
a bonding wire connected to a surface of the metal region in the metal bonding member.

2. The semiconductor device according to claim 1, wherein
the metal region has a porosity lower than a porosity of the porous region.

3. The semiconductor device according to claim 1, further comprising a conductor between the insulating substrate and the metal bonding member.

4. The semiconductor device according to claim 2, further comprising a conductor between the insulating substrate and the metal bonding member.
